(19) United States
(12) Patent Application Publication
(10) Pub. No.: US 2011/0165435 A1
(43) Pub. Date: Jul. 7, 2011

(54) SANITARY OBJECT

(76) Inventor: Axel ROST, Lahr (DE)

(21) Appl. No.: 13/042,822

(22) Filed: Mar. 8, 2011

Related U.S. Application Data
(63) Continuation of application No. PCT/EP2009/006411, filed on Sep. 4, 2009.

(30) Foreign Application Priority Data
Sep. 10, 2008 (DE) 10 2008 046 673.5

(51) Int. Cl. B32B 9/00; B32B 15/04; C23C 16/44; C23C 28/00

(52) U.S. Cl. 428/634; 428/408; 427/249.1; 205/194

(57) ABSTRACT

A method for manufacturing composite bodies is provided by applying a firmly adhering layer to substrates composed of plastic or metal, particularly stainless steel, brass, aluminum, or zinc, it is provided that a layer composed of carbon is deposited on the substrate by means of chemical vapor deposition and a hard material layer is deposited on the carbon layer by means of physical vapor deposition.

This nonprovisional application is a continuation of International Application No. PCT/EP2009/006411, which was filed on Sep. 4, 2009, and which claims priority to German Patent Application No. DE 10 2008 046 673.5, which was filed in Germany on Sep. 10, 2008, and which are both herein incorporated by reference.

### BACKGROUND OF THE INVENTION

1. Field of the Invention

The present invention relates to a sanitary object with a composite body and a method for the production thereof. The invention relates to composite bodies and coatings of articles of daily use such as, for example, plumbing fixtures and installation products, showerheads, outlets, or trims and cover plates, which, on the one hand, must be resistant to corrosion, friction, and chemical stress and, on the other, are supposed to have a decorative surface with a predefined coloring. Numerous methods for applying decorative layers are known from the state of the art. Apart from wet chemical methods, such as galvanic processes, methods are known such as PVD (physical vapor deposition), CVD (chemical vapor deposition), and coating methods and the combinations thereof, by means of which layers with a specific coloring can be deposited on the objects.

2. Description of the Background Art

It is known, further, to use hard material layers and wear protection layers for coating surfaces and, for example, for producing cutting tools by means of physical methods (PVD) such as arc, sputter, or electron beam evaporation or laser evaporation methods. The properties of the layers are determined by the deposition technology and the process management. Further, the layer properties are defined by the chemical composition. Primarily, highly diverse layer structures and compositions can be achieved with the arc and sputter technology due to the possible target compositions and the choice of reaction gases.

European Pat. App. No. EP 1 033 416 A1, for example, discloses producing at least one corrosion protection layer and an outer layer of zirconium, nitrogen, carbon, and/or hafnium by means of PVD coating on a substrate, whereby the outer layer forms a passive layer under the effect of air or water.

Furthermore, DE 100 05 614 A1 discloses the production of an object with specific layer sequences by means of PVD technology, whereby the layers are formed alternately of carbon and carbide. The carbide layers include, in turn, a carbide of at least one element in the form of a metal and/or silicon and/or boron. The topmost layer of the layer sequence in this case includes carbon, which has predominantly sp³ bonds and a layer thickness of about 500 nm.

A ceramic substrate with a diamond layer and a cover layer of chromium carbide, chromium nitride, or chromium carbonitride for the production of cutting tools is known from U.S. Pat. No. 5,543,210 A.

### SUMMARY OF THE INVENTION

It is therefore an object of the present invention to provide a method with which a coating with low wear, but a relatively high hardness can be produced on almost any sanitary object, and to provide sanitary objects with such a coating.

A sanitary object with a composite body comprising a substrate and a coating is provided with the invention, whereby the substrate has plastic or metal, particularly brass, aluminum, zinc, or stainless steel, and the coating has a layer of carbon and a cover layer, which is produced by means of a PVD method on the carbon layer. Coating is understood to be the application of a firmly adhering layer of a formless substance to a workpiece. The layer and substrate form a composite body made of different substances. The layer assumes the contact function, such as protection against chemical or corrosive attack and against tribological stress, influences the frictional behavior, or is used for visual or decorative purposes, whereas the substrate assumes the support function, whereby its properties can be adapted to the specific stress without consideration of the contact behavior. Additional property advantages are achieved by the application of multiple layers. In the present case, a higher hardness is achieved by the arrangement of a carbon layer and a subsequent PVD cover layer on the surface of the composite body than could be produced by the application of the PVD cover layer alone. The hardness values represent a direct comparison quantity for the abrasive wear resistance of a material or body. It becomes clear from this that the wear resistance of the composite body is increased by the application of the carbon layer despite its placement below the PVD cover layer, which is used as the decorative surface layer.

The carbon layer in this regard is provided as amorphous carbon with any sp²·sp³ hybridization ratios. The term “diamond-like carbon” or “DLC” (diamond-like carbon or diamond-like coating) is used for these layers.

According to an advantageous embodiment of the invention, the composite body of the sanitary object is provided with a cover layer as a hard material layer of titanium, tantalum, molybdenum, and tungsten or a compound of titanium, tantalum, molybdenum, and tungsten with carbon, nitrogen, boron, or silicon or combinations thereof.

Alternatively thereto, the cover layer of zirconium, chromium, hafnium, vanadium, or niobium or a compound of zirconium, chromium, hafnium, vanadium, or niobium with carbon, nitrogen, boron, or silicon or combinations thereof can also be provided.

A refinement of the invention provides that a metallic layer or a series of layers is arranged as an intermediate layer between the substrate and carbon layer.

Copper or nickel, for example, is provided as the metallic layer on the substrate. The layer sequence in this regard depends substantially on the type of substrate. Another metallic layer of nickel and/or chromium can be provided. Depending on the desired degree of gloss, a series of galvanic layers of copper, nickel, and then chromium are also possible.

In the case of brass substrates, the intermediate layers have a first nickel layer and a following chromium layer. In the case of an aluminum substrate, a copper layer is arranged first, then a nickel layer, and finally a chromium layer. Depending on the desired surface, in this case, the layer thicknesses can vary. Because the first layer is also used for leveling the surface structure, it has at least a layer thickness of 15 μm. The following layers of copper or nickel are also provided with a layer thickness of at least 10 μm. In the nickel layers, the desired surface quality is already influenced by the choice of nickel, depending on whether a glossy nickel layer or a matt nickel layer is arranged. The final decorative cover layer has at least a layer thickness of 0.2 μm.

Furthermore, the invention provides a method for the production of composite bodies by the application of a firmly adhering layer to substrates of plastic or metal, particularly stainless steel, brass, aluminum, or zinc, in which a layer of carbon is deposited on the substrate by means of chemical vapor deposition (CVD) and a cover layer on the carbon layer by means of physical vapor deposition (PVD).

To apply the carbon layer, the substrate is placed in a vacuum chamber of a reactor for chemical vapor deposition and the air is pumped out of the chamber. Next, the carbon layer is deposited by one of the following conventional methods: direct ion beam deposition, double ion beam deposition, or glow discharge, RF plasma, DC plasma, or microwave plasma deposition from a carbon-containing gas or a carbon-containing vapor, which can also be mixed with hydrogen, nitrogen-containing gases, oxygen-containing gases, and/or an inert gas. Further, methods such as electron beam evaporation, ion-assisted evaporation, ion beam-cathode sputtering, or ion-assisted sputtering from a solid carbon target or combinations of the mentioned methods are also possible.

A refinement of the invention provides that before the application of the carbon layer at least one metallic layer is applied to the substrate. These can be applied by means of a wet chemical or galvanic method.

The coating is especially suitable for objects exposed to frequent chemical stress or friction or a combination of both stresses. It is therefore advantageous to produce sanitary objects such as sanitary fittings and parts thereof, installation elements, showerheads, outlets, trims, cover plates, pressure plates, and/or actuation elements according to the method of the invention.

Furthermore, it is also possible to produce the cited objects free of nickel or chromium (VI) compounds by omitting these metallic intermediate layers. For objects of this type, whose substrates includes, for example, brass, a copper layer is applied galvanically for leveling the surface and for producing a specific degree of gloss. It is immaterial in this case that the hardness of the copper layer is low in comparison with nickel and chromium. The desired surface properties are then achieved by the application and the combination of DLC and a cover layer.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a cross section through the layer structure of an object of the invention;

FIG. 2 shows a cross section through the layer structure of a second object of the invention;

FIG. 3 shows a cross section through the layer structure of a third object of the invention;

FIG. 4 shows a cross section through the layer structure of a fourth object of the invention; and

FIG. 5 shows a cross section through the layer structure of a fifth object of the invention.

### DETAILED DESCRIPTION

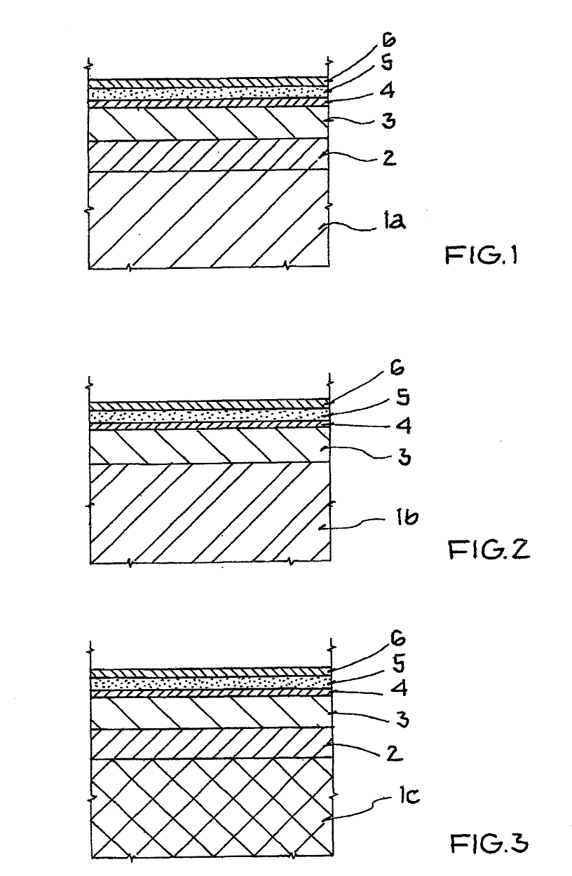

The object shown in FIG. 1 has a base material 1a of aluminum. A copper layer 2 with a layer thickness of preferably 20 μm was then deposited in a galvanic process on the base material 1a. A nickel layer 3 with a layer thickness of preferably 15 μm was deposited by additional galvanic process steps. Next, a chromium layer 4 with a thickness of preferably 0.3 μm was applied. A diamond-like or amorphous carbon layer (DLC) 5 with a layer thickness of preferably 1 μm was deposited thereafter in the CVD process on metallic layers 2, 3, 4. The carbon layer in this regard has a largely flatly built structure. The hardness of this layer, which was deposited by means of hexane as the reaction gas, is approximately 3000 Vickers hardnesses (HV).

After this, to achieve a chrome look, a cover layer of chromium, chromium carbide, or chromium carbonitride was applied by means of the PVD method. The layer thickness of a PVD layer 6 is preferably 0.2 μm here. In a determination of the hardness at the surface of the finished composite body, a value was measured that was considerably higher than the hardness of PVD layer 6 alone. The increase in the hardness value due to the combination of layers 5 and 6 compared with PVD layer 6 taken separately was about 30%.

The object shown in FIG. 2 has a base material 1b of brass. A nickel layer 3 with a layer thickness of preferably 15 μm and then a chromium layer 4 with a thickness of preferably 0.3 μm were deposited in a galvanic process on the base material. Thereafter, first a diamond-like or amorphous carbon layer 5 in the CVD process with a layer thickness of preferably 1 μm and finally a cover layer 6 with a layer thickness of preferably 0.2 μm were applied to metallic layers 3, 4.

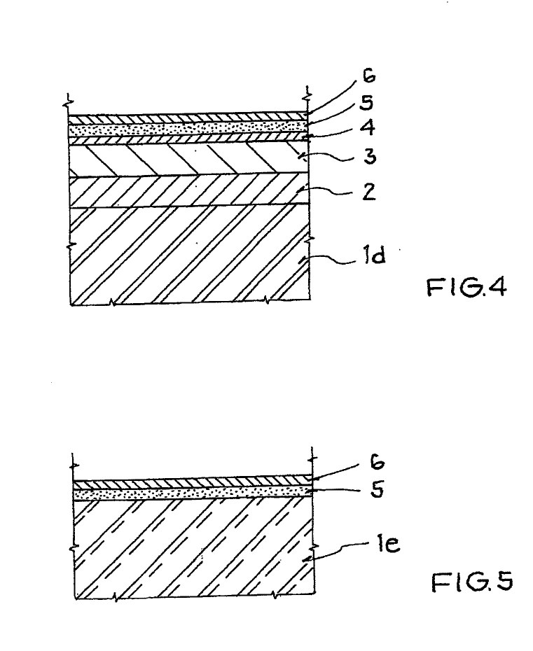

The object shown in FIG. 3 has a base material 1c of plastic, preferably ABS. A copper layer 2 with a layer thickness of preferably 20 μm was then deposited in a galvanic process on the base material 1c. A nickel layer 3 with a layer thickness of preferably 15 μm and then a chromium layer 4 with a thickness of preferably 0.3 to 0.4 μm were deposited by means of additional galvanic process steps. The following carbon and cover layer corresponds to the structure of layers 5 and 6 of the composite body of FIG. 1 and FIG. 2.

The object shown in FIG. 4 has a base material 1d of zinc die casting. A copper layer 2 with a layer thickness of preferably 20 μm was deposited in a galvanic process on the base material 1d. A nickel layer 3 with a layer thickness of preferably 20 μm and a chromium layer 4 with a thickness of preferably 0.3 to 0.4 μm were deposited by means of additional galvanic process steps. The following carbon layer and cover layer correspond to the structure of layers 5 and 6 of the composite body of FIGS. 1 through 3.

The object shown in FIG. 5 has a base material 1e of stainless steel. A diamond-like or amorphous carbon layer 5 with a layer thickness of preferably 1 μm was deposited directly in the CVD process on base material 1e. The final surface layer has a chromium layer or a hard material layer with a layer thickness of preferably 0.2 μm, produced by the PVD method.

Tests by the applicant have shown that the properties of the DLC layer, characterized by a high corrosion, scratch, and wear resistance, are retained also after the application of the PVD layer. Thus, the coloring of the objects can be formed after the DLC layer, without the desired requirements for hardness and abrasion resistance being substantially affected.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A sanitary object with a composite body made of a substrate and a coating, the sanitary object comprising:
a substrate made of plastic or metal; and
a coating formed of a layer of carbon and a cover layer, which is produced by a physical vapor deposition (PVD) method on the carbon layer.

2. The sanitary object with a composite body according to claim 1, wherein amorphous carbon with any sp²·sp³ hybridization ratios is provided as the carbon layer.

3. The sanitary object with a composite body according to claim 1, wherein the cover layer is provided as a hard material layer of titanium, tantalum, molybdenum, or tungsten or a compound of titanium, tantalum, molybdenum, or tungsten with carbon, nitrogen, boron, or silicon or combinations thereof.

4. The sanitary object with a composite body according to claim 1, wherein the cover layer is made of zirconium, chromium, hafnium, vanadium, or niobium or a compound of zirconium, chromium, hafnium, vanadium, or niobium with carbon, nitrogen, boron, or silicon or combinations thereof.

5. The composite body according to claim 1, wherein a metallic layer or series of layers is arranged as an intermediate layer between the substrate and carbon layer.

6. The composite body according to claim 5, wherein a metallic layer of copper or nickel is provided.

7. The composite body according to claim 5, wherein a series of metallic layers of copper and nickel is provided, and wherein the copper layer is arranged contiguous to the substrate.

8. The composite body according to claim 6, wherein another metallic layer of chromium is provided.

9. A method for producing sanitary objects with composite bodies, the method comprising:
applying a firmly adhering layer to substrates formed of plastic or metal, particularly stainless steel, brass, aluminum, or zinc;
depositing a layer of carbon on the substrate by chemical vapor deposition (CVD); and
depositing a cover layer on the carbon layer by physical vapor deposition (PVD).

10. The method according to claim 9, wherein, before the application of the carbon layer, at least one metallic layer is applied to the substrate.

11. The method according to claim 10, wherein the metallic layer or series of layers is applied by a wet chemical or galvanic method.

12. The method according to claim 10, wherein the metallic layer or metallic layers of copper and/or nickel are provided.

13. The method according to claim 11, wherein another metallic layer of chromium is provided.

14. The sanitary object according to claim 1, wherein the metal is brass, aluminum, zinc, or stainless steel.
